(19) United States
(12) Patent Application Publication
(10) Pub. No.: US 2009/0034423 A1
(43) Pub. Date: Feb. 5, 2009

(54) Automated detection of TCP anomalies

(76) Inventors: Anthony Terrance Coon, Cupertino, CA (US); Jeffrey Paul Radick, Sunnyvale, CA (US); Holly Moore, Richmond, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/888,002

(22) Filed: Jul. 30, 2007

(51) Int. Cl. G01R 31/08

(52) U.S. Cl. 370/244

(57) ABSTRACT

One embodiment relates to an automated method of detecting transmission control protocol (TCP) anomalies. A TCP connection is selected to be monitored. Packets communicated for the TCP connection are scanned in chronological order of packet communication times. A signature is created for the connection based on the scanned packets, and said signature is characterized to detect anomalous behavior of the TCP connection being monitored. Other embodiments, aspects and features are also disclosed.

### BACKGROUND

1. Field of the Invention

The present application relates generally to data networking.

2. Description of the Background Art

Traditionally, transmission control protocol (TCP) connections are evaluated using “manual” techniques. For example, a computer network debugging tool known as tcpdump may be used to provide a segment-by-segment text transcript of the connection. In addition, a tool known as tcptrace may be used to create graphical representations of the connection.

However, using tcpdump and/or tcptrace requires the time and skill of a knowledgeable engineer who physically examines (i.e. reviews) the output of the tool(s) do detect anomalous aspects for further investigation. Hence, this conventional approach is ill-suited for large-scale monitoring or testing.

### BRIEF DESCRIPTION OF THE DRAWINGS

FIG. 1 is a high-level diagram depicting an automated technique for detecting TCP anomalies in accordance with an embodiment of the invention.

FIG. 2 is a schematic diagram of a computer system or apparatus which may be configured to implement an automated technique for detecting TCP anomalies in accordance with an embodiment of the invention.

FIG. 3 is a flow chart showing a method of detecting TCP anomalies by characterizing a signature of a TCP connection in accordance with an embodiment of the invention.

FIG. 4 is a flow chart showing a method of detecting TCP anomalies using a finite state machine in accordance with an embodiment of the invention.

FIG. 5 is a flow chart showing a method of detecting TCP anomalies using a Markov chain in accordance with an embodiment of the invention.

FIG. 6 is a flow chart showing a method of detecting TCP anomalies using a neural network in accordance with an embodiment of the invention.

### DETAILED DESCRIPTION

The present disclosure provides automated methods of detecting TCP anomalies. By abstracting aspects of the TCP connection into a behavioral model, the present disclosure enables automated evaluation and comparison of connections. The automated evaluation may report only the connections that fall outside predetermined parameters. Advantageously, due to the automated nature of this technique, the evaluation may be performed on a large scale so as to cover a system with very many TCP connections to be monitored. In addition, the automated evaluation may be faster, more consistent, and more reliable than the conventional manual technique.

With this automated technique, the time of a knowledgeable engineer does not have to be spent on reviewing the output of tools such as tcpdump and tcptrace. Rather, the time of the knowledgeable engineer may be better focused on TCP connections that are deemed by the automated technique to be exceptional or anomalous.

A TCP connection is defined by a large and varied number of factors. The factors may include, for example, the number of segments of the connection, the number of segments of each type (SYN, PUSH, and so on), the elapsed time between sending a segment and acknowledge, the number of out-of-order segments, the number of duplicate acknowledgements and retransmissions, and other data. With this data extracted and reduced to a signature or series of mathematical expressions, the connection may be characterized by automated evaluation using a computer program.

A connection using a known and consistent client and server over a stable link will have little variance in the connection data. Varying the conditions under which the same connection takes place will result in a different set of connection data.

Over the range of normal and expected conditions, a representative set of data under the various conditions will emerge. From this data, statistics such as a standard deviation or expected variance may be established. With expected and actual data, a computer program may be configured to rapidly point out connections that are exceptional, making such exceptional connections candidates for manual evaluation by a knowledgeable engineer.

In addition, connections may be compared. For example, the same stable and consistent client and server connection performed on two disparate platforms may be compared. This allows for large-scale comparison of the TCP signatures across many platforms.

Advantageously, the modeling of TCP connections disclosed herein provides an economical and efficient means for evaluation and comparison of TCP behavior, especially where such evaluation involves many tens or hundreds of connections. Hence, this method enables large-scale, automated testing of TCP connections under varied conditions and across varied platforms. Without this technique, a knowledgeable engineer is limited to trying to “eyeball” scan tens or even hundreds of text files or graphs.

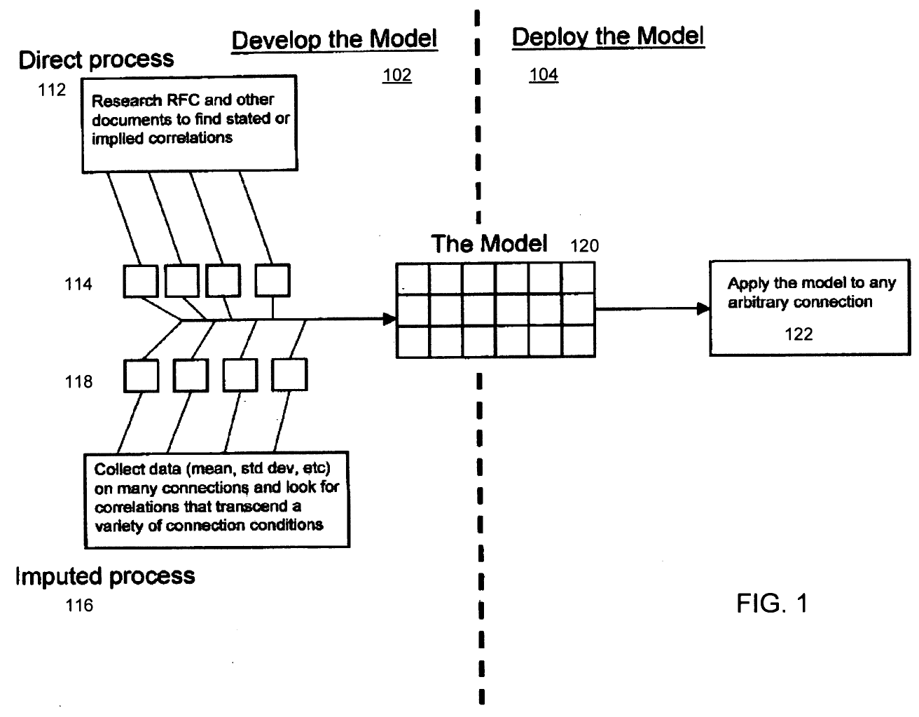

FIG. 1 is a high-level diagram depicting an automated technique for detecting TCP anomalies in accordance with an embodiment of the invention. The technique may be divided into two phases: a first phase where a model 120 is developed 102, and a second phase where the model 120 is used or deployed 104.

Developing 102 the model 120 may involve a direct process 112 and/or an imputed process 116.

In the direct process 112, stated or implied correlations may be found by researching the request for comment (RFC) for the TCP/IP protocol. These correlations may be coded into computer-readable program code components 114 for use in the model 120.

In the imputed process 116, data may be collected (including data statistics such as mean, standard deviation, and so on) on many TCP connections. Correlations may then be looked for or discovered, where the correlations may transcend a variety of connection conditions. These correlations may be coded into computer-readable program code components 118 for use in the model 120.

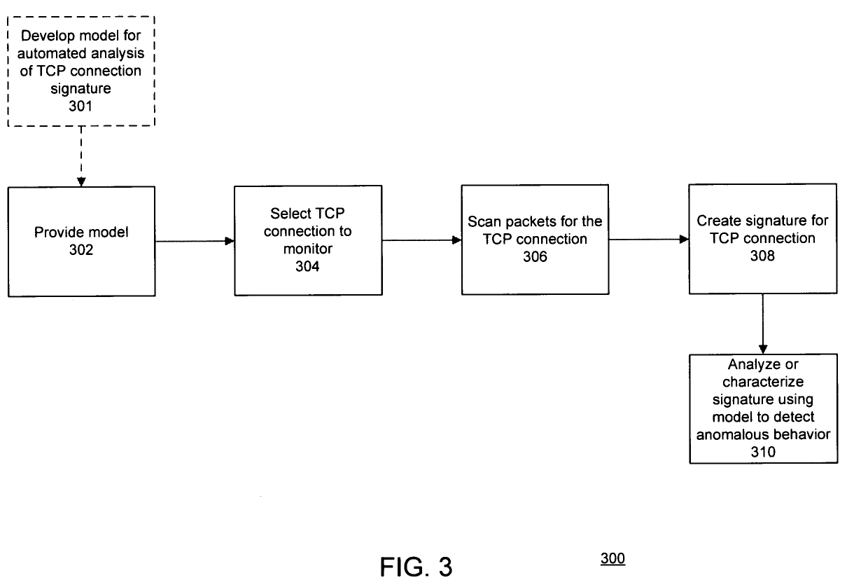

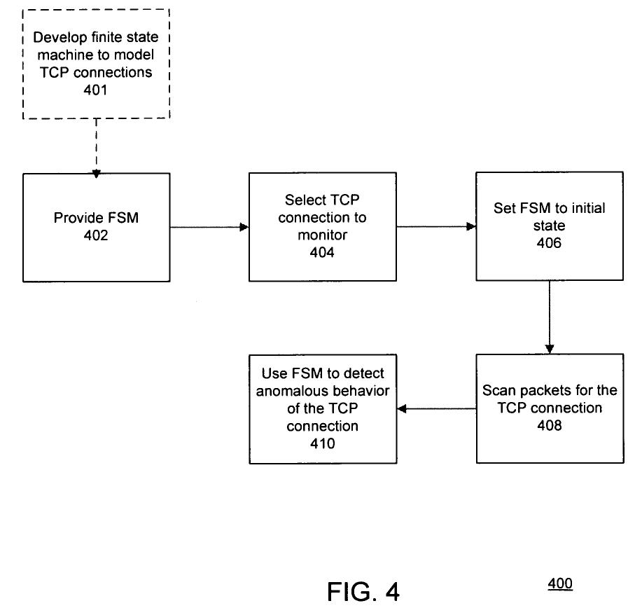

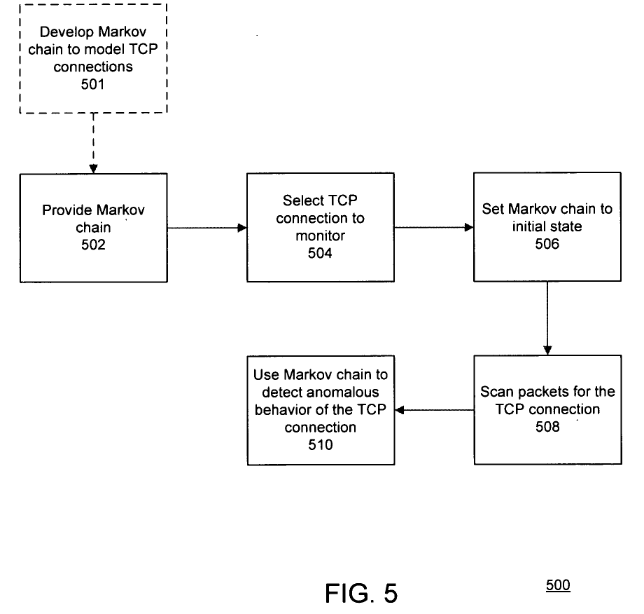

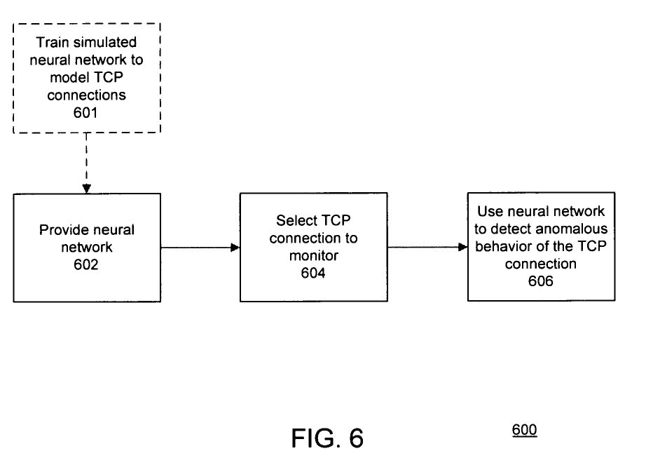

The model 120 may thus be formed from the computer-readable program code components (114 and/or 118) from the direct process 112 and/or from the imputed process 116. The model 120 may then be applied 122 to any arbitrary TCP connection in the deployment phase 104. In other words, the model may be deployed for the automated detection of TCP anomalies. The model 120 may be implemented based on the analysis of connection signatures (see FIG. 3), or based on a finite state machine (see FIG. 4), or based on a Markov chain (see FIG. 5), or based on a neural network (see FIG. 6), for example.

An example of correlations developed from a direct process 112 is as follows. In this example, an expected number of segments from a sender may be calculated, and the expected number may be compared with the actual number. The connection may be flagged if the comparison indicates a material difference.

The calculation of the expected number of segments may be performed as follows, for example. The number of send( ) calls from the sending side and the size of the send( ) message are input. In addition, the Maximum Segment Size (MSS) is calculated from the SYN segments. From these elements, the expected number of segments may be calculated.

The calculated number of segments from the sending side may then be compared with the actual number found in a scan of the trace file (e.g., the tcpdump file) for the connection. The connection may then be flagged if there is a material difference between the two. For example, the connection may be flagged if the difference is greater than a predetermined threshold fraction or number.

For instance, in a specific example, a tcpdump output parser found 33 segments from the sender. For comparison, the calculated number of segments was 32.

An example of correlations developed from an imputed process 116 is as follows. In this example, round trip time statistics for a connection without impairments are calculated. If a round trip time for a connection being monitored is outside, for example, two standard deviations from the mean, then the connection may be flagged.

For each ACK packet from the receiving side, a calculation is made of the time delta (time difference) between the time the last ACK'd PSH segment was sent and the time of the ACK. The statistics calculated may include a mean and standard deviation for the series of time deltas for a connection without impairment. The statistics may be calculated based on a relatively large number of time deltas, for example, one hundred or more. This is so the standard deviation statistic has significance.

When the connection is monitored, PSH/ACK pairs are found where the time delta falls outside two standard deviations from the mean in the calculated statistics. If analysis indicates that these deviations from the mean are significant, then the segment identifiers may be stored, and the connection may be flagged for further review.

To illustrate, the following is a heavily-edited slice of a tcpdump listing. There are two PSH segments, followed by an ack. In both cases, the ACK acknowledges the bytes in both of the PSH segments. The ACK of 13449, ACKs the segment immediately above.

The round-trip time is measured from the timestamp on the second PSH (12001:13449) and the timestamp on the ack of 13449.

P 11049:12001(952) ack 1 win 33304<nop,nop,timestamp 16212362 16189414>
12001:13449(1448) ack 1 win 33304<nop,nop,timestamp 16212372 16189414>
ack 13449 win 32580<nop,nop,timestamp 16189425 16212362>
P 13449:14401(952) ack 1 win 33304<nop,nop,timestamp 16212373 16189425>
14401:15849(1448) ack 1 win 33304<nop,nop,timestamp 16212383 16189425>
ack 15849 win 32580<nop,nop,timestamp 16189437 16212373>

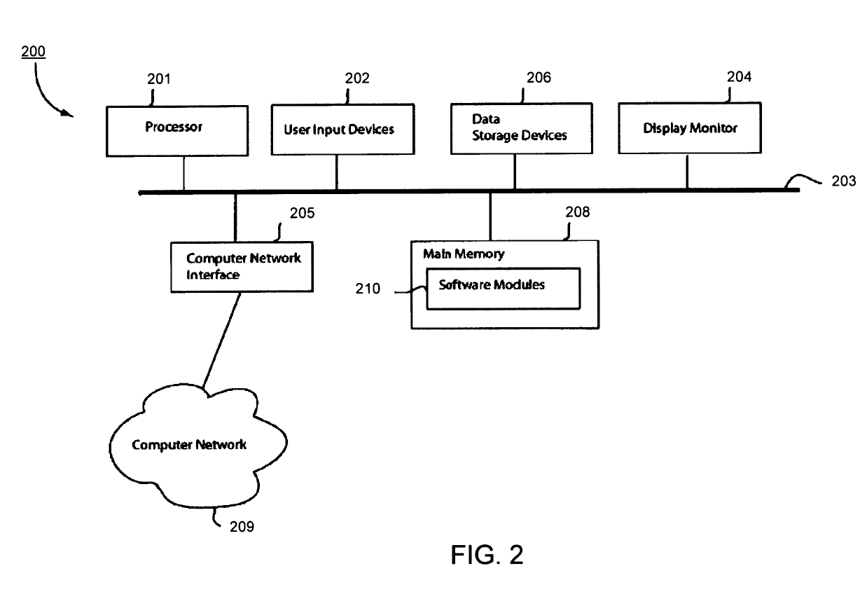

FIG. 2 is a schematic diagram of an example computer system or apparatus 200 which may be configured to implement an automated technique for detecting TCP anomalies in accordance with an embodiment of the invention. The computer 200 may have less or more components than illustrated. The computer 200 may include a processor 201, such as those from the Intel Corporation or Advanced Micro Devices, for example. The computer 200 may have one or more buses 203 coupling its various components. The computer 200 may include one or more user input devices 202 (e.g., keyboard, mouse), one or more data storage devices 206 (e.g., hard drive, optical disk, USB memory), a display monitor 204 (e.g., LCD, flat panel monitor, CRT), a computer network interface 205 (e.g., network adapter, modem), and a main memory 208 (e.g., RAM).

In the example of FIG. 2, the main memory 208 may be configured to include software modules 210, which may be software components to perform computer-implemented procedures discussed herein. The software modules 210 may be loaded from the data storage device 206 to the main memory 208 for execution by the processor 201. The computer network interface 205 may be coupled to a computer network 209, which in this example includes the Internet.

FIG. 3 is a flow chart showing a method 300 of detecting TCP anomalies by characterizing a signature of a TCP connection in accordance with an embodiment of the invention. In a first or preliminary step, a model may be developed 301 for the automated analysis of TCP connection signatures. As discussed above in relation to FIG. 1, such model development may involve direct and/or imputed processes.

Thereafter, the model may be provided 302 to be applied in the automated detection of TCP anomalies. A TCP connection is selected 304 to be monitored. Packets for the selected TCP connection may then be scanned 306. The packets that are scanned preferably include both packets sent and received, and the packets are preferably scanned in chronological order of packet communication times (i.e. the times when a packet is transmitted or received). Thereafter, a signature may be created 308 for the selected TCP connection by processing or analyzing the scanned packets. The signature may then be characterized or analyzed 310 to detect anomalous behavior, if any, of the TCP connection.

In accordance with an embodiment of the invention, by characterizing or analyzing 310 the signature, a suspect event is identified from a group of suspect events consisting of data retransmissions, duplicate acknowledgements received, and dropped connections. Any suspect events may be correlated with system data to provide a further level of information on the anomalous behavior. For example, the suspect event may be correlated with the number of simultaneous connections, the number of pending connection requests, an address resolution protocol (ARP) traffic level, an overall traffic level on a local area network, interface types, card types, link speeds, maximum transmission unit (MTU) sizes, a system load average, a number of interrupts per second, a disk activity level, or other system data.

FIG. 4 is a flow chart showing a method of detecting TCP anomalies using a finite state machine in accordance with an embodiment of the invention. In a first or preliminary step, a finite state machine (FSM) may be developed 401 for the automated analysis of TCP connections. As discussed above in relation to FIG. 1, such model development may involve direct and/or imputed processes. For the imputed processes, data from a multitude of TCP connections may be used in developing the FSM.

Thereafter, the FSM may be provided 402 for the automated detection of TCP anomalies. A TCP connection is selected 404 to be monitored, and the FSM may be set 406 to an initial state. Packets for the selected TCP connection are scanned 408. The packets that are scanned preferably include both packets sent and received, and the packets are preferably scanned in chronological order of packet communication times (i.e. the times when a packet is transmitted or received). Thereafter, the FSM may be used 410 to detect anomalous behavior, if any, of the selected TCP connection. Transitions between states of the FSM may be determined as the packets are scanned in chronological order so as to detect the anomalous behavior, if any.

In accordance with an embodiment of the invention, by using 410 the FSM, a suspect event is identified from a group of suspect events consisting of data retransmissions, duplicate acknowledgements received, and dropped connections. Any suspect events may be correlated with system data to provide a further level of information on the anomalous behavior. For example, the suspect event may be correlated with the number of simultaneous connections, the number of pending connection requests, an address resolution protocol (ARP) traffic level, an overall traffic level on a local area network, interface types, card types, link speeds, maximum transmission unit (MTU) sizes, a system load average, a number of interrupts per second, a disk activity level, or other system data.

FIG. 5 is a flow chart showing a method of detecting TCP anomalies using a Markov chain in accordance with an embodiment of the invention. In a first or preliminary step, a Markov chain may be developed 501 for the automated analysis of TCP connections. As discussed above in relation to FIG. 1, such model development may involve direct and/or imputed processes. For the imputed processes, data from a multitude of TCP connections may be used in developing the Markov chain. In a Markov chain (also called a Markov model), there are probabilities for making state transitions between the various states of the model (chain). This contrasts with a finite state machine which is deterministic.

Thereafter, the Markov chain may be provided 502 for the automated detection of TCP anomalies. A TCP connection is selected 504 to be monitored, and the Markov chain may be set 506 to an initial state. Packets for the selected TCP connection are scanned 508. The packets that are scanned preferably include both packets sent and received, and the packets are preferably scanned in chronological order of packet communication times (i.e. the times when a packet is transmitted or received). Thereafter, the Markov chain may be used 510 to detect anomalous behavior, if any, of the selected TCP connection. Transitions between states of the Markov chain may be determined probabilistically as the packets are scanned in chronological order so as to detect the anomalous behavior, if any.

In accordance with an embodiment of the invention, by using 510 the Markov chain, a suspect event is identified from a group of suspect events consisting of data retransmissions, duplicate acknowledgements received, and dropped connections. Any suspect events may be correlated with system data to provide a further level of information on the anomalous behavior. For example, the suspect event may be correlated with the number of simultaneous connections, the number of pending connection requests, an address resolution protocol (ARP) traffic level, an overall traffic level on a local area network, interface types, card types, link speeds, maximum transmission unit (MTU) sizes, a system load average, a number of interrupts per second, a disk activity level, or other system data.

FIG. 6 is a flow chart showing a method of detecting TCP anomalies using a neural network in accordance with an embodiment of the invention. In a first or preliminary step, a computer-simulated neural network may be developed and trained 601 for the automated analysis of TCP connections. As discussed above in relation to FIG. 1, such model development may involve direct and/or imputed processes. For the imputed processes, data from a multitude of TCP connections may be used in training the neural network.

Thereafter, the neural network may be provided 602 for the automated detection of TCP anomalies. A TCP connection is selected 604 to be monitored. Data or characteristics of the TCP connection are input into the neural network, so that the neural network may be used 606 to detect anomalous behavior, if any, of the selected TCP connection.

In the above description, numerous specific details are given to provide a thorough understanding of embodiments of the invention. However, the above description of illustrated embodiments of the invention is not intended to be exhaustive or to limit the invention to the precise forms disclosed. One skilled in the relevant art will recognize that the invention can be practiced without one or more of the specific details, or with other methods, components, etc. In other instances, well-known structures or operations are not shown or described in detail to avoid obscuring aspects of the invention. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the claims. Rather, the scope of the invention is to be determined by the following claims, which are to be construed in accordance with established doctrines of claim interpretation.

What is claimed is:

1. An automated method of detecting transmission control protocol (TCP) anomalies, the method comprising:
selecting a TCP connection to monitor;
scanning packets communicated for the TCP connection in chronological order of packet communication times;
creating a signature for the connection based on the scanned packets; and
characterizing said signature to detect anomalous behavior of the TCP connection being monitored.

2. A computer-implemented method of detecting transmission control protocol (TCP) anomalies, the method comprising:
providing a finite state machine to model TCP connections;
selecting a TCP connection to monitor;
setting the finite state machine in an initial state;
scanning packets communicated for the TCP connection in chronological order of packet communication times; and
using the finite state machine to detect anomalous behavior of the TCP connection being monitored.

3. The computer-implemented method of claim 2, further comprising developing the finite state machine using data from a multitude of TCP connections.

4. The computer-implemented method of claim 2, further comprising developing the finite state machine using correlations derived from a request for comment for TCP.

5. The computer-implemented method of claim 2, further comprising determining transitions between states of the finite state machine as the packets are scanned in chronological order so as to detect said anomalous behavior.

6. The computer-implemented method of claim 2, wherein said scanning of packets includes identifying a suspect event from a group of suspect events consisting of data retransmissions, duplicate acknowledgements received, and dropped connections.

7. The computer-implemented method of claim 6, further comprising correlating said suspect event with system data.

8. The computer-implemented method of claim 7, wherein said system data include at least one datum from a group of data consisting of a number of simultaneous connections, a number of pending connection requests, an address resolution protocol (ARP) traffic level, an overall traffic level on a local area network, interface types, card types, link speeds, maximum transmission unit (MTU) sizes, a system load average, a number of interrupts per second, and a disk activity level.

9. A computer-implemented method of detecting transmission control protocol (TCP) anomalies, the method comprising:
providing a Markov chain to model TCP connections;
selecting a TCP connection to monitor;
setting the Markov chain in an initial state;
scanning packets communicated for the TCP connection in chronological order of packet communication times; and
using the Markov chain to detect anomalous behavior of the TCP connection being monitored.

10. The computer-implemented method of claim 9, further comprising developing the Markov chain using data from a multitude of TCP connections.

11. The computer-implemented method of claim 9, further comprising developing the finite state machine using correlations derived from a request for comment for TCP.

12. The computer-implemented method of claim 9, further comprising determining transitions between states of the Markov chain as the packets are scanned in chronological order so as to detect said anomalous behavior.

13. The computer-implemented method of claim 9, wherein said scanning of packets includes identifying a suspect event from a group of suspect events consisting of data retransmissions, duplicate acknowledgements, and dropped connections.

14. The computer-implemented method of claim 13, further comprising correlating said suspect event with system data.

15. The computer-implemented method of claim 13, wherein said system data include at least one datum from a group of data consisting of a number of simultaneous connections, a number of pending connection requests, an address resolution protocol (ARP) traffic level, an overall traffic level on a local area network, interface types, card types, link speeds, maximum transmission unit (MTU) sizes, a system load average, a number of interrupts per second, and a disk activity level.

16. A computer-implemented method of detecting transmission control protocol (TCP) anomalies, the method comprising:
providing a simulated neural network to model TCP connections;
selecting a TCP connection to monitor;
using the simulated neural network to detect anomalous behavior of the TCP connection being monitored.

17. The computer-implemented method of claim 16, further comprising training the neural network using data from a multitude of TCP connections.

18. A computer apparatus configured for automated detection of transmission control protocol (TCP) anomalies, the apparatus comprising:
a processor configured to execute computer-readable program code;
data storage communicatively coupled to the processor and configured to store the computer-readable program code and computer-readable data;
computer-readable program code in said data storage configured to select a TCP connection to monitor;
computer-readable program code in said data storage configured to scan packets communicated for the TCP connection in chronological order of packet communication times;
computer-readable program code in said data storage configured to create a signature for the connection based on the scanned packets; and
computer-readable program code in said data storage configured to characterize said signature to detect anomalous behavior of the TCP connection being monitored.
